(19) United States
(12) Patent Application Publication
(10) Pub. No.: US 2013/0038401 A1
(43) Pub. Date: Feb. 14, 2013

(54) RADAR SYSTEM INCLUDING BALUN

(71) Applicants: Su Han KIM, Seongnam-si (KR); Hyung Suk Ham, Yongin-si (KR)

(72) Inventors: Su Han KIM, Seongnam-si (KR); Hyung Suk Ham, Yongin-si (KR)

(73) Assignee: MANDO CORPORATION

(21) Appl. No.: 13/569,615

(22) Filed: Aug. 8, 2012

(30) Foreign Application Priority Data
Aug. 9, 2011 (KR) 10-2011-0079068

(51) Int. Cl. H03H 7/42

(52) U.S. Cl. 333/26

(57) ABSTRACT

A balun includes a first port connected with a port connection part, a second port connected with the port connection part at a point separated by λ₀/4 from a connection point of the first port and the port connection part, and a third port connected with the port connection part at a point separated by λ₀/2 from a connection point of the second port and the port connection part. A maximum width of the second port and the third port are larger than a width at a region connected with the port connection part and larger than a width at a distal end, respectively. And a maximum distance between the second port and the third port is larger than a distance between the connection points with the port connection part and larger than a distance between the distal ends.

### BACKGROUND OF THE INVENTION

1. Field of the Invention

The present invention relates to a radar system including a balun.

2. Description of the Prior Art

Recently, automobiles have provided users with various safety functions or convenient functions as well as many electronic devices.

For example, an automobile includes a radar system, and the radar system performs a smart cruise control function or a lane departure prevention function (lane keeping assisting system) by detecting a distance, a relative velocity, etc., between the automobile itself and a neighboring vehicle.

The radar system may detect a distance, a relative velocity, etc., between the automobile itself and a neighboring vehicle by transmitting/receiving a radar signal through an antenna for transmission and an antenna for reception and processing the transmitted/received radar signal.

Recently, the radar system mounted on a vehicle transmits/receives a radar signal of several tens of GHz to several hundreds of GHz, so that devices included in the radar system become complicated.

### SUMMARY OF THE INVENTION

Accordingly, the present invention has been made to solve the above-mentioned problems occurring in the prior art, and the present invention provides a balun having a simple structure.

In accordance with an aspect of the present invention, there is provided a balun including: a first port to/from which a signal having a wavelength of λ₀ is input/output, the first port being connected with a port connection part; a second port connected with the port connection part at a point separated by λ₀/4 from a connection point of the first port and the port connection part; and a third port connected with the port connection part at a point separated by λ₀/2 from a connection point of the second port and the port connection part to have an impedance matching with the second port, wherein a maximum width of the second port is larger than a width of the second port in a region in which the second port is connected with the port connection part and is larger than a width of a distal end of the second port, a maximum width of the third port is larger than a width of the third port in a region in which the third port is connected with the port connection part and is larger than a width of a distal end of the third port, and a maximum distance between the second port and the third port which face each other is larger than a distance from the connection point of the port connection part and the second port to the connection point of the port connection part and the third port and is larger than a distance from the distal end of the second port to the distal end of the third port.

The port connection part and the first to third ports are formed on a single-layer substrate.

The second port and the third port include a first sub port, a second sub port, and a third sub port, respectively, the second sub port is disposed between the first sub port and the third sub port, and the second sub port of the second port and the second sub port of the third port have a bent shape such that a distance between the second sub port of the second port and the second sub port of the third port which face each other is decreased.

The third sub port of the second port and the third sub port of the third port have a bent shape such that a distance between the third sub port of the second port and the third sub port of the third port which face each other is decreased.

A width of the second sub port is larger than that of the first sub port and is larger than that of the third sub port.

As described above, according to the present invention, the impedance matching between the second port and the third port is realized without an isolation port, thereby achieving the simplification of the balun structure and a decrease in a process and a time for forming the isolation port.

### BRIEF DESCRIPTION OF THE DRAWINGS

FIG. 1 illustrates a general balun including an isolation port.

FIG. 2 illustrates a balun according to a first embodiment of the present invention.

FIG. 3 illustrates a balun according to a second embodiment of the present invention.

FIG. 4 is a graph illustrating a characteristic of a balun according to the first and second embodiments.

### DETAILED DESCRIPTION OF THE EXEMPLARY EMBODIMENTS

Hereinafter, an exemplary embodiment of the present invention will be described with reference to the accompanying drawings in detail. In the following description and drawings, the same reference numerals are used to designate the same or similar components, and so repetition of the description on the same or similar components will be omitted. Further, in the following description, a detailed explanation of known related functions and constitutions may be omitted so as to avoid unnecessarily obscuring the subject manner of the present invention.

Further, in describing the constructional elements of the present invention, the terms of a first, a second, A, B, (a), (b), or the like, can be used. Such a term is only for discriminating the constructional element from another constructional element, and does not limit the essential feature, order, or sequence of the constructional element, or the like. If one constructional element is “coupled to”, “assembled with”, or “connected to” another constructional element, one constructional element is directly coupled to or connected to another constructional element, but it can be understood as another different constructional element can be “coupled”, “assembled”, or “connected” between each constructional element.

A radar system according to an exemplary embodiment of the present invention includes balun. The word “balun” is a portmanteau blending the words balanced and unbalanced. The balun may be used for converting a balanced signal into an unbalanced signal or converting an unbalanced signal to a balanced signal.

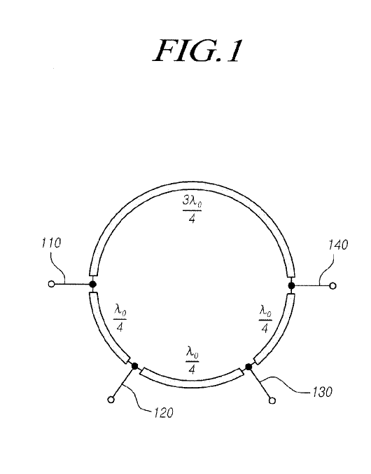

As illustrated in FIG. 1, a general balun includes four ports 110, 120, 130, and 140. When a signal is input in the first port 110, signals having a phase difference of 180° are output through the second and fourth ports 120 and 140. On the contrary, when signals having a phase difference of 180° are input through the second and fourth ports 120 and 140, a synthesized signal of the signals having the phase difference of 180° is output through the first port 110. In FIG. 1, λ₀ may be a wavelength of the signal input or output through the first port 110.

As described above, the balun may branch the input signal into the signals having the phase difference of 180° or distribute input power, and performs a function of synthesizing the signals having the phase difference of 180° input through the separate ports and outputting the synthesized signal through one port. The balun may be included in a radar system requiring the aforementioned function.

In this case, in order to match impedances of the output ports 120 and 140, i.e. in order to reduce or remove a difference of impedances of the output ports 120 and 140, a device having appropriate impedance, such as resistance, may be connected to the isolation port.

As described above, a frequency of the transmission/reception signal of the radar system of a vehicle ranges from several tens of GHz to several hundreds of GHz, so that the isolation port is not certain. Accordingly, the exemplary embodiment of the present invention provides a balun without an isolation port.

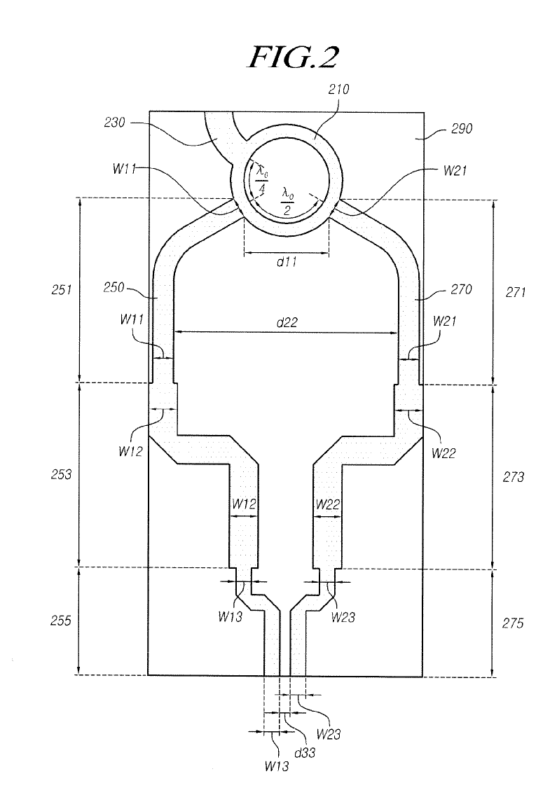

FIG. 2 illustrates a balun according to a first embodiment of the present invention. As illustrated in FIG. 2, the balun according to the first embodiment of the present invention includes a port connection part 210, a first port 230, a second port 250, and a third port 270.

The first port 230 is connected with the port connection part 210.

The second port 250 is connected with the port connection part 210 at a point separated by λ₀/4 from a connection point of the first port 230 and the port connection part 210.

The third port 270 is connected with the port connection part 210 at a point separated by λ₀/2 from a connection point of the second port 250 and the port connection part 210 to have an impedance matching with the second port 250.

In this case, λ₀ may be a wavelength of a signal input or output through the first port 230, and the port connection part 210 may have a hollow shape.

When a signal is input in the balun according to the first embodiment of the present invention through the first port 230, signals having a phase difference of 180° are output through the second port 250 and the third port 270. Further, signals having a phase difference of 180° are input through the second port 250 and the third port 270, a synthesized signal of the signals having the phase difference of 180° may be output through the first port 230.

Since the balun according to the first embodiment of the present invention includes no isolation port, a width of the second port 250 and a width of the third port 270 are changed for the impedance matching between the second port 250 and the third port 270.

That is, a maximum width W12 of the second port 250 may be larger than a width W11 of the second port 250 in a region in which the second port 250 is connected with the port connection part 210 and larger than a width W13 of a distal end of the second port 250. Further, a maximum width W22 of the third port 270 may be larger than a width W21 of the third port 270 in a region in which the third port 270 is connected with the port connection part 210, and be larger than a width W23 of a distal end of the third port 270.

In a case of the first embodiment of the present invention, the second port 250 and the third port 270 includes first sub ports 251 and 271, second sub ports 253 and 273, and third sub ports 255 and 275, respectively, and the second sub ports 253 and 273 may be disposed between the first sub ports 251 and 271 and the third sub ports 255 and 275. In this case, the widths W12 and W22 of the second sub ports 253 and 273 may be larger than the widths W11 and W21 of the first sub ports 251 and 271 and may be larger than the widths W13 and W23 of the third sub ports 255 and 275.

In this case, since impedance of a conductive body is in inverse proportionate to a width of the conductive body, impedances of the second sub ports 253 and 273 may be smaller than impedances of the first sub ports 251 and 271 and impedances of the third sub ports 255 and 275. As such, when the widths of the second sub ports 253 and 273 are appropriately set, the impedance matching between the second port 250 and the third port 270 may be realized.

In the meantime, a maximum distance d22 between the second port 250 and the third port 270 which face each other may be larger than a distance d11 from the connection point of the port connection part 210 and the second port 250 to the connection point of the port connection part 210 and the third port 270 and may be larger than a distance d33 from the distal end of the second port 250 to the distal end of the third port 270.

Further, in a case of the first embodiment, the second sub ports 253 and 273 of the second port 250 and the third port 270 may have a bent shape such that the distance between the second sub port 253 of the second port 250 and the second sub port 273 of the third port 270 which face each other is decreased. Likewise, the third sub ports 255 and 275 of the second port 250 and the third port 270 may have a bent shape such that the distance between the third sub port 255 of the second port 250 and the third sub port 275 of the third port 270 which face each other is decreased.

As described above, since the second sub ports 253 and 273 and the third sub ports 255 and 275 have the bent shape, the distance between the second sub ports 253 and 273 and the distance between the third sub ports 255 and 275 are changed and thus capacitance between the second sub ports 253 and 273 and capacitance between the third sub ports 255 and 275 are changed. Accordingly, when the distance between the second sub ports 253 and 273 and the distance between the third sub ports 255 and 275 are appropriately set, the impedance matching between the second port 250 and the third port 270 may be realized.

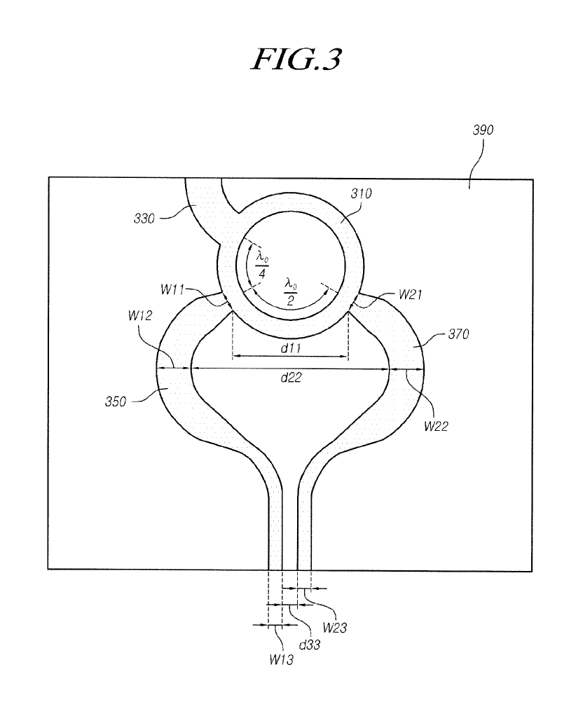

FIG. 3 illustrates a balun according to a second embodiment of the present invention. As illustrated in FIG. 3, the balun according to the second embodiment of the present invention includes a port connection part 310, a first port 330, a second port 350, and a third port 370.

The first port 330 is connected with the port connection part 310.

The second port 350 is connected with the port connection part 310 at a point separated by λ₀/4 from a connection point of the first port 330 and the port connection part 310.

The third port 370 is connected with the port connection part 310 at a point separated by λ₀/2 from a connection point of the second port 350 and the port connection part 310 to have an impedance matching with the second port 350.

In this case, λ₀ may be a wavelength of a signal input or output through the first port 330, and the port connection part 310 may have a hollow shape.

Likewise to the first embodiment, in a case of the second embodiment, when a signal is input through the first port 330, signals having a phase difference of 180° are output through the second port 350 and the third port 370. Further, signals having a phase difference of 180° are input through the second port 350 and the third port 370, a synthesized signal of the signals having the phase difference of 180° may be output through the first port 330.

Since the balun according to the second embodiment of the present invention includes no isolation port, a width of the second port 350 and a width of the third port 370 are changed for the impedance matching between the second port 350 and the third port 370.

That is, a maximum width W12 of the second port 350 may be larger than a width W11 of the second port 350 in a region in which the second port 350 is connected with the port connection part 310 and larger than a width W13 of a distal end of the second port 350. Further, a maximum width W22 of the third port 370 may be larger than a width W21 of the third port 370 in a region in which the third port 370 is connected with the port connection part 310, and larger than a width W23 of a distal end of the third port 370.

As described above, since impedance of a conductive body is in inverse proportionate to a width of the conductive body, when the widths W11 and W21 of the second port 350 and the third port 370 are appropriately set, the impedance matching between the second port 350 and the third port 370 may be realized.

In the meantime, as described above, in the second embodiment of the present invention, when a distance between the second port 350 and the third port 370 which face each other are appropriately set, the impedance matching between the second port 350 and the third port 370 may also be realized. That is, a maximum distance d22 between the second port 350 and third port 370 which face each other may be larger than a distance d11 from the connection point of the port connection part 310 and the second port 350 to the connection point of the port connection part 310 and the third port 370 and larger than a distance d33 from the distal end of the second port 350 to the distal end of the third port 370.

Accordingly, when the distance between the second port 350 and the third port 370 is appropriately set, the capacitance between the second port 350 and the third port 370 is controlled, so that the impedance matching between the second port 250 and the third port 270 may be realized.

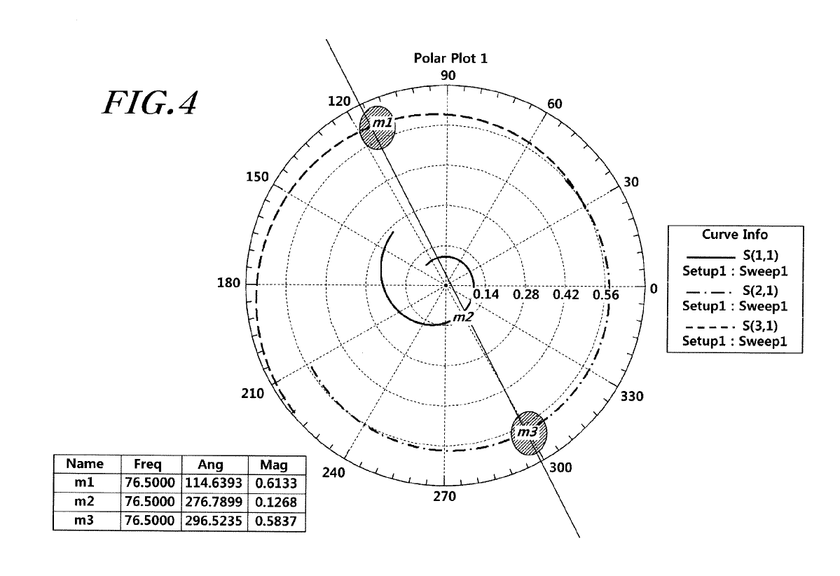

FIG. 4 is a graph illustrating a characteristic of the balun according to the first and second embodiments.

m1 and m3 correspond to the second port 250 or 350 and the third port 270 or 370, respectively. When a signal having a phase angle of about 114° is output from the second port 250 or 350, a signal having a phase angle of about 296° is output from the third port 270 or 370. Accordingly, it can be seen that since the phase difference between the signals output from the second port 250 or 350 and the third port 270 or 370 is approximately 180°, the balun according to the first and second embodiments of the present invention normally performs its function without an isolation port.

The balun according to the embodiments of the present invention performs a normal operation without an isolation port, so that the balun has a simple structure and may process a signal in a band of several tens of GHz or several hundreds of GHz used in a radar system of a vehicle. In order to normally process a signal in a band of several tens of GHz or several hundreds of GHz, a waveguide type having a 3D-shape may be used, but in the balun according to the embodiments of the present invention, the port connection part and the first to third ports may be implemented on a single layer substrate 290 or 390 without an isolation port.

Even if it was described above that all of the components of an embodiment of the present invention are coupled as a single unit or coupled to be operated as a single unit, the present invention is not necessarily limited to such an embodiment. That is, among the components, one or more components may be selectively coupled to be operated as one or more units.

In addition, since terms, such as “including,” “comprising,” and “having” mean that one or more corresponding components may exist unless they are specifically described to the contrary, it shall be construed that one or more other components can be included. All of the terminologies containing one or more technical or scientific terminologies have the same meanings that persons skilled in the art understand ordinarily unless they are not defined otherwise. A term ordinarily used like that defined by a dictionary shall be construed that it has a meaning equal to that in the context of a related description, and shall not be construed in an ideal or excessively formal meaning unless it is clearly defined in the present specification.

Although a preferred embodiment of the present invention has been described for illustrative purposes, those skilled in the art will appreciate that various modifications, additions and substitutions are possible, without departing from the scope and spirit of the invention as disclosed in the accompanying claims. Therefore, the embodiments disclosed in the present invention are intended to illustrate the scope of the technical idea of the present invention, and the scope of the present invention is not limited by the embodiment. The scope of the present invention shall be construed on the basis of the accompanying claims in such a manner that all of the technical ideas included within the scope equivalent to the claims belong to the present invention.

What is claimed is:

1. A balun comprising:
a first port to/from which a signal having a wavelength of λ₀ is input/output, the first port being connected with a port connection part;
a second port connected with the port connection part at a point separated by λ₀/4 from a connection point of the first port and the port connection part; and
a third port connected with the port connection part at a point separated by λ₀/2 from a connection point of the second port and the port connection part to have an impedance matching with the second port,
wherein a maximum width of the second port is larger than a width of the second port in a region in which the second port is connected with the port connection part and larger than a width of a distal end of the second port,
a maximum width of the third port is larger than a width of the third port in a region in which the third port is connected with the port connection part and larger than a width of a distal end of the third port, and
a maximum distance between the second port and the third port which face each other is larger than a distance from the connection point of the port connection part and the second port to the connection point of the port connection part and the third port and larger than a distance from the distal end of the second port to the distal end of the third port.

2. The balun as claimed in claim 1, wherein the port connection part and the first to third ports are formed on a single-layer substrate.

3. The balun as claimed in claim 1, wherein the second port and the third port comprises a first sub port, a second sub port, and a third sub port, respectively,
the second sub port is disposed between the first sub port and the third sub port, and
the second sub port of the second port and the second sub port of the third port have a bent shape such that a distance between the second sub port of the second port and the second sub port of the third port which face each other is decreased.

4. The balun as claimed in claim 3, wherein the third sub port of the second port and the third sub port of the third port have a bent shape such that a distance between the third sub port of the second port and the third sub port of the third port which face each other is decreased.

5. The balun as claimed in claim 3, wherein a width of the second sub port is larger than that of the first sub port and larger than that of the third sub port.

6. A radar system comprising a balun, the balun comprising:
a first port to/from which a signal having a wavelength of λ₀ is input/output, the first port being connected with a port connection part;
a second port connected with the port connection part at a point separated by λ₀/4 from a connection point of the first port and the port connection part; and
a third port connected with the port connection part at a point separated by λ₀/2 from a connection point of the second port and the port connection part to have an impedance matching with the second port,
wherein a maximum width of the second port is larger than a width of the second port in a region in which the second port is connected with the port connection part and larger than a width of a distal end of the second port,
a maximum width of the third port is larger than a width of the third port in a region in which the third port is connected with the port connection part and larger than a width of a distal end of the third port, and
a maximum distance between the second port and the third port which face each other is larger than a distance from the connection point of the port connection part and the second port to the connection point of the port connection part and the third port and is larger than a distance from the distal end of the second port to the distal end of the third port.
